(19) United States
(12) Patent Application Publication
(10) Pub. No.: US 2025/0149356 A1
(43) Pub. Date: May 8, 2025

(54) PROTECTIVE MEMBER FORMING APPARATUS

(71) Applicant: DISCO CORPORATION, Tokyo (JP)

(72) Inventor: Yoshikuni MIGIYAMA, Tokyo (JP)

(73) Assignee: DISCO CORPORATION, Tokyo (JP)

(21) Appl. No.: 18/934,364

(22) Filed: Nov. 1, 2024

(30) Foreign Application Priority Data
Nov. 2, 2023 (JP) 2023-188080

(51) Int. Cl. H01L 21/67; B05C 5/02; B05C 11/00

(52) U.S. Cl. CPC H01L 21/6715; B05C 5/02; B05C 11/00

(57) ABSTRACT

A protective member forming apparatus configured to spread a liquid resin, cure the liquid resin and form a protect member on an entire surface of a wafer on one side includes a sheet holder to hold a sheet, a wafer holder to locate the wafer to face the sheet holder and hold the wafer thereat, a liquid resin feeding nozzle to feed the liquid resin onto the sheet held by the sheet holder or onto the wafer held by the wafer holder, a lift/lower device to lift or lower the sheet holder and the wafer holder relatively, a first emitter to emit electromagnetic waves to the liquid resin and cure the liquid resin, and a second emitter to emit UV rays or plasma at a surface of the sheet held by the sheet holder and improve wettability of the surface of the sheet.

### CROSS REFERENCE TO RELATED APPLICATION

This application is based upon and claims the benefit of priority from the prior Japanese Patent Application No. 2023-188080, filed on Nov. 2, 2023; the entire contents of which are incorporated herein by reference.

### FIELD

The present disclosure relates to a protective member forming apparatus.

### BACKGROUND

A protective member forming apparatus for forming a protective member on a surface of a wafer is known. The protective member forming apparatus may, as disclosed in, for example, Japanese Patent Laid-Open Publication Nos. 2021-061333 and 2022-020286, form a protective member by feeding a predetermined amount of liquid resin to a sheet, pressing the liquid resin with a wafer held by a holder, spreading the liquid resin over a surface on one side of the wafer entirely, and allowing the liquid resin to cure. As such, the protective member to protect the one side of the wafer composed of a sheet and resin may be formed.

The conventional protective member forming apparatus may have a technical problem such that spreading the liquid resin requires time. In order to address this problem, for example, the liquid resin may be handled in a closed and decompressed chamber so that the liquid may be promoted to spread faster.

However, even in the closed and decompressed chamber, the liquid resin may not spread easily at a portion on a central part of the wafer, which is farther from a gas-liquid interface, and the benefit of the decompressed environment may be limited. In this regard, a technique that may further reduce the time for forming the protective member has been desired.

### SUMMARY

In view of the problem, the present disclosure is directed to providing a technique to efficiently form a protective member.

A protective member forming apparatus according to an embodiment of the present invention is configured to spread a liquid resin on an entire surface of a wafer on one side, cure the liquid resin and form a protective member to protect the entire surface of the wafer on the one side, the protective member forming apparatus includes a sheet holder configured to hold a sheet, a wafer holder configured to locate the wafer to face the sheet holder and hold the wafer thereat, a liquid resin feeding nozzle configured to feed the liquid resin onto the sheet held by the sheet holder or onto the wafer held by the wafer holder, a lift/lower device configured to lift or lower the sheet holder and the wafer holder relatively, a first emitter configured to emit electromagnetic waves to the liquid resin and cure the liquid resin, and a second emitter configured to emit UV rays or plasma at a surface of the sheet held by the sheet holder and improve wettability of the surface of the sheet.

### BRIEF DESCRIPTION OF DRAWINGS

FIG. 1 is a schematic perspective view of a protective member forming apparatus according to an embodiment.

FIG. 2 is an illustrative view of a sheet-feeding process in forming of the protective member.

FIG. 3 is an illustrative view of a wettability-forming process in forming of the protective member.

FIG. 4 is an illustrative view of a liquid-resin feeding process in forming of the protective member.

FIG. 5 is an illustrative view of a wafer-holding process in forming of the protective member.

FIG. 6 is an illustrative view of a press-spreading process in forming of the protective member.

FIG. 7 is an illustrative view of a curing process in forming of the protective member.

FIG. 8 is an illustrative view of another wettability-forming process in forming of a protective member.

FIG. 9 is an illustrative view of another liquid-resin feeding process in forming of a protective member.

### DESCRIPTION OF EMBODIMENTS

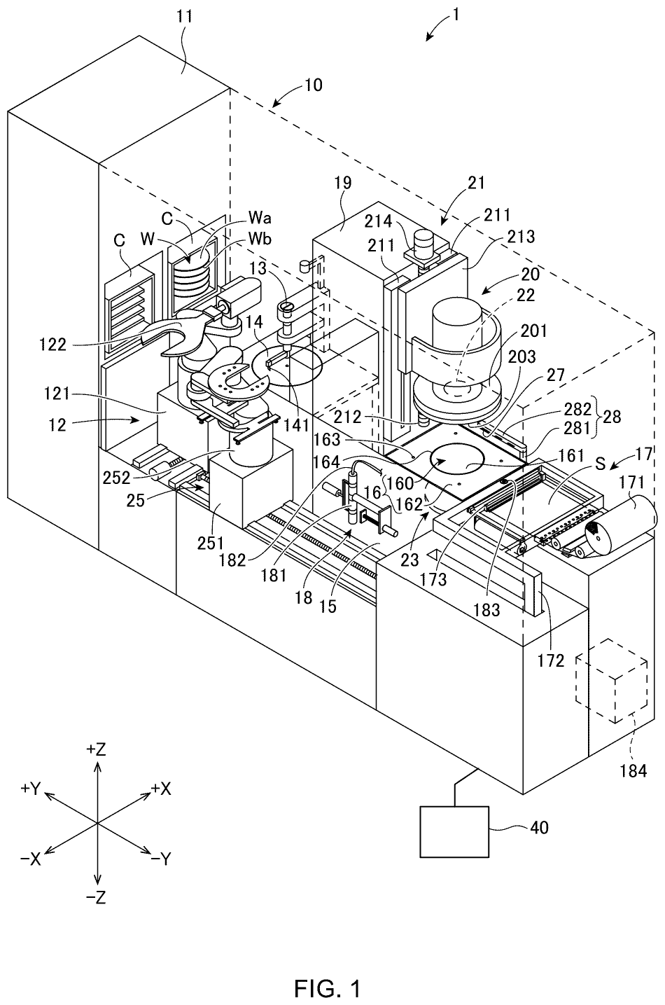

Hereinafter, with reference to the accompanying drawings, the protective member forming apparatus according to the embodiment of the present disclosure will be described. FIG. 1 is a schematic perspective view of the protective member forming apparatus according to the embodiment.

An X-axis direction, a Y-axis direction, and a Z-axis direction shown in the drawings are orthogonal to one another. The X-axis direction and the Y-axis direction are substantially horizontal direction, and the Z-axis direction is an up-down direction (vertical direction).

A protective member forming apparatus 1 shown in FIG. 1 is an example of an apparatus that may form a protective member H composed of cured resin HM and a sheet S (see FIG. 7) for protecting an entire surface of a wafer W on one side. The protective member forming apparatus 1 may form the protective member H by allowing liquid resin M to spread on the surface of the wafer W and cure between the wafer W and the sheet S. In the following description, the liquid resin M before curing and the cured resin HM may be distinguished by the different reference signs appended thereto.

The protective member forming apparatus 1 is configured to improve wettability of a surface of the sheet S, onto which the liquid resin M is dropped, so that the liquid resin M may spread between the wafer W and the sheet S over the entire surface of the wafer W on the one side in a short time. Below will be described the configuration of the protective member forming apparatus 1.

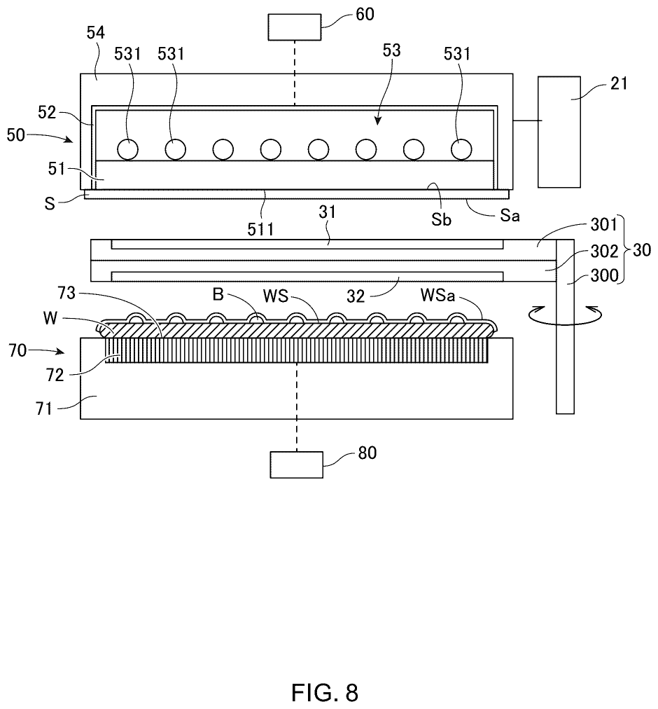

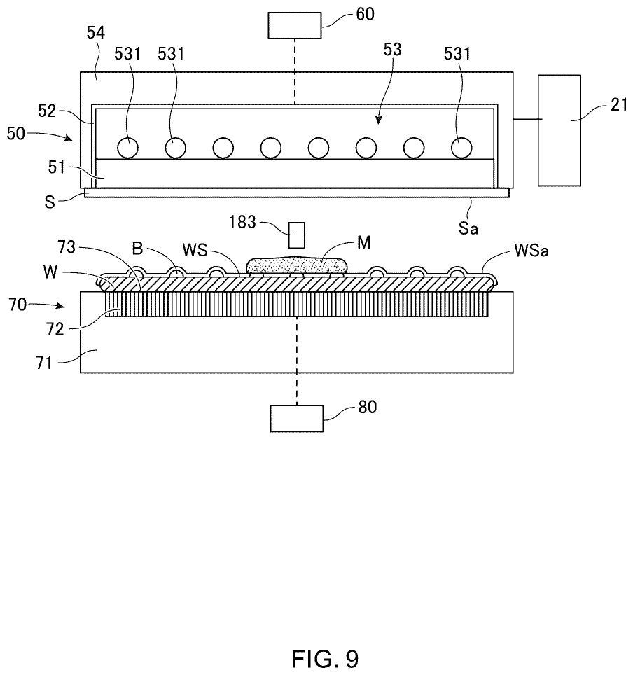

An example of a configuration to feed the liquid resin M to the surface of the sheet S for forming the protective member H will be described below. In this respect, the liquid resin M may not necessarily be fed to the sheet S but may optionally be fed to the wafer W, as long as the liquid resin M is fed to an area between the sheet S and the wafer W. For example, as will be described below with reference to FIGS. 8 and 9, the liquid resin M may be fed to a surface of a sheet (wafer sheet WS) formed on the surface of the wafer W or may be fed directly to the surface of the wafer W.

FIG. 1 shows the protective member forming apparatus 1, in which an exterior housing 10 is drawn in broken lines, and interior components therein are drawn fluoroscopically. A side of the wafer W facing upward and the other side of the wafer W facing downward when being processed in the protective member forming apparatus 1 will be referred to as an upper surface Wa and a lower surface Wb, respectively.

The wafer W may be, for example, a disk-shaped as-sliced wafer cut from a cylindrical ingot of, for example, silicon. However, the wafer W may not necessarily be limited to the as-sliced wafer but may be a device wafer on which devices are formed or may be a bumped wafer.

The protective member forming apparatus 1 has a cassette storage 11 on a side in the +Y direction in the exterior housing 10. The cassette storage 11 is loaded with cassettes C, in which a plurality of wafers W may be stored.

At a position on a side of the cassette storage 11 in the +Y direction, a sheet cutting table 14 is arranged. The sheet cutting table 14 is provided with a sheet cutter 141, which may cut the sheet S adhered to the wafer W along an outline of the wafer W.

On a side of the sheet cutting table 14 in the −X direction, a first conveyer 12 that may load or unload the cassette C with the wafers W is located. The first conveyer 12 has a robot hand 122 supported by a pedestal 121 and may move the wafer W between the cassette C stowed in the cassette storage 11 and a temporary resting table 13 by moving the pedestal 121 in the X-axis direction and operating the robot hand 122.

The protective member forming apparatus 1 has a base 15 on a side of the sheet cutting table 14 in the −Y direction. The base 15 includes a glass table 160 (sheet holder) formed of a light-transmittable material such as quartz glass. The glass table 160 is formed in a shape of a disk. An upper surface of the glass table 160 forms a flat placement surface 161, on which the sheet S may be placed. Moreover, a supporting table 162 is provided to support the glass table 160. The supporting table 162 has four suction holes 163 formed on an upper side thereof. The suction holes 163 are connected with a suction source (not shown) to suction the sheet S.

The protective member forming apparatus 1 has a sheet conveyer 17, which may convey and place the sheet S on the placement surface 161 of the glass table 160 and an upper surface of the supporting table 162. The sheet conveyer 17 includes a sheet feeder 171 to support the sheet S in a rolled form, an arm 172 movable in the Y-axis direction, and a cramp 173 attached to a lateral surface of the arm 172. The sheet conveyer 17 may place the sheet S on the placement surface 161 of the glass table 160 and the upper surface of the supporting table 162 by operating the cramp 173 to hold the sheet S unrolled from the sheet feeder 171 and moving the arm 172 in the +Y direction to pull the sheet S. Further, the sheet conveyer 17 may operate the suction source to generate the suction force to act on the four suction holes 163, and thereby the supporting table 162 may hold the sheet S.

The sheet S is made of a light-transmittable material. The sheet S may be, for example, a film made of polyethylene terephthalate or the like. Optionally, the sheet S may be made of a material other than polyethylene terephthalate.

At a boundary between an outer periphery of the placement surface 161 of the glass table 160 and an inner periphery of the supporting table 162, an annular suction hole 164 connected to the suction source (not shown) is formed. The suction force being operated may act on the suction hole 164, and thereby the sheet S placed on the placement surface 161 is suctioned and held thereat. The glass table 160 and the supporting table 162 compose a glass table 16 in a broader sense, which functions as a sheet holder in the protective member forming apparatus 1.

In proximity to the glass table 16, a resin feeder 18 to feed a predetermined amount of the liquid resin M to the sheet S held by the glass table 16 is located. The resin feeder 18 includes a dispenser 181, which is connected to a tank 184 located inside the base 15, a connecting tube 182 extending from the dispenser 181, and a resin feeding nozzle 183 connected with the connecting tube 182.

The resin feeding nozzle 183 is a liquid resin feeding nozzle located in a lower part of the arm 172. The arm 172 is movable in the Y-axis direction by the sheet conveyer 17, and thereby the resin feeding nozzle 183 may be set either in a state where the resin feeding nozzle 183 is located at a position between the glass table 16 and a wafer holder 20 for holding the wafer W or in a state where the resin feeding nozzle 183 is withdrawn from the position between the glass table 16 and the wafer holder 20. The wafer holder 20 will be described further below.

The liquid resin M stored in the tank 184 may be conveyed by the dispenser 181 through the connecting tube 182 and drip down from the resin feeding nozzle 183 to be fed to the sheet S. An amount of the liquid resin M to be fed from the resin feeding nozzle 183 is adjustable by the dispenser 181.

The liquid resin M has a property to cure in reaction to an external stimulus. In the present embodiment, UV-curable liquid resin M that may cure by being exposed to ultraviolet rays is used. Optionally, however, the liquid resin M may be a thermally curable resin.

The protective member forming apparatus 1 has the wafer holder 20 for holding the wafer W located on top of the glass table 16. The wafer holder 20 is supported by a column 19, and the column 19 is arranged to protrude upward from the base 15 at a position on a side of the glass table 16 in the +Y direction. The column 19 is provided with a lift/lower device 21, which may move (lift or lower) the wafer holder 20 in the Z-axis direction to approach or separate from the glass table 16.

The lift/lower device 21 includes a pair of guide rails 211 and a ball screw 212 extending in the Z-axis direction, and a lifting table 213 supported movably with respect to the pair of guide rails 211 in the Z-axis direction. The lift/lower device 21 may rotate the ball screw 212 with a driving force from a motor 214, and thereby the lifting table 213 may move in the Z-axis direction along the pair of guide rails 211.

The wafer holder 20 is supported by the lifting table 213 and may move in the Z-axis direction along with the movement of the lifting table 213. In other words, the lift/lower device 21 is configured to lift or lower the wafer holder 20 with respect to the glass table 16.

The wafer holder 20 has a disk-shaped holding table 201. On a lower side of the holding table 201, a disk-shaped porous member 202 (see FIG. 5) is provided. A lower surface of the porous member 202 provides a wafer holding surface 203 located above the glass table 16. The wafer holding surface 203 spreads substantially in parallel to the placement surface 161, on which the sheet S may be placed. In other words, the wafer holder 20 is located to face the glass table 16.

The porous member 202 is in communication with the suction source (not shown) through a suction path. The suction force generated by the suction source may be applied to the porous member 202, and thus the porous member 202 may suction an upper surface Wa of the wafer W. Thereby, the wafer W may be held on the wafer holding surface 203.

The wafer holder 20 has a load detector 22. The load detector 22 may detect load on the lower surface Wb of the wafer W in the Z-axis direction.

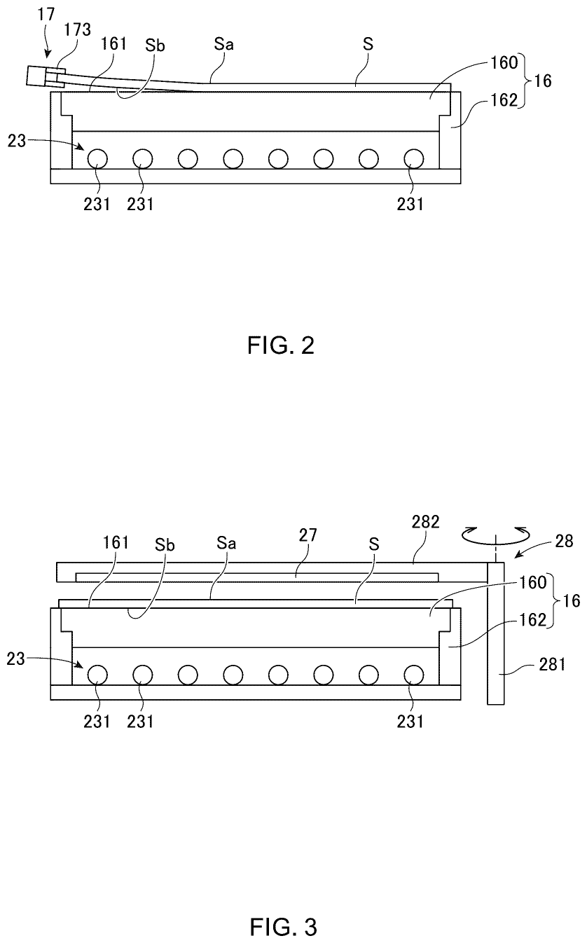

At a position below the round glass table 160 that forms the glass table 16, a UV-emitting unit 23 is located. The UV-emitting unit 23 may emit UV rays at the liquid resin M dropped on the sheet S on the placement surface 161. The UV-emitting unit 23 may be arranged in, for example, an inner space enclosed by the supporting table 162 and the glass table 160 (see FIG. 2). The UV-emitting unit 23 includes a plurality of UV emitters 231 (see FIG. 7), each of which may emit a UV ray, and may emit UV rays as an external stimulus at the liquid resin M through the light-transmittable glass table 160 and the sheet S to cure the liquid resin M. The light source to be used in the UV emitters 231 may be, for example, LEDs.

The UV emitters 231 is an example of the curing unit for applying an external stimulus to the liquid resin and curing the liquid resin M. In a case where the liquid resin M is thermally curable resin, the protective member forming apparatus 1 may be equipped with infrared emitters that may emit infrared rays to apply heat to the liquid resin M in place of the UV emitters 231.

On a side of the base 15 in the −X direction, a second conveyer 25 is located. The second conveyer 25 has a robot hand 252 supported by a pedestal 251 and may move the wafer W between the temporary resting table 13 and the wafer holder 20 by moving the pedestal 251 in the Y-axis direction and operating the robot hand 252. Moreover, the second conveyer 25 may convey the wafer W between the glass table 16 and the sheet cutting table 14.

The protective member forming apparatus 1 further has a sheet wettability forming unit 27 and an insertion/withdrawal device 28. The sheet wettability forming unit 27 is fixed to the insertion/withdrawal device 28 located in proximity to the glass table 16.

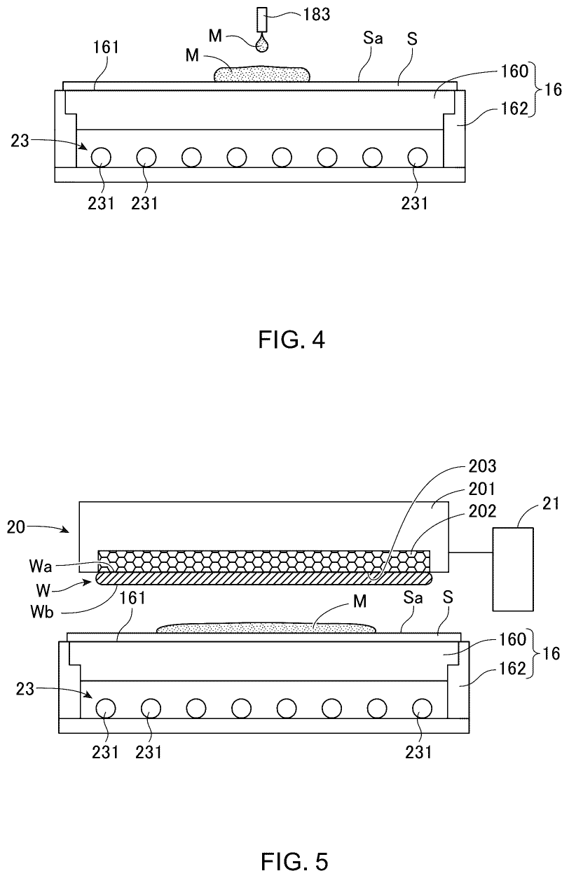

The sheet wettability forming unit 27 is a unit, which may emit UV rays at the surface of the sheet S held on the glass table 16 and thereby improve wettability of the surface of the sheet S. In particular, the sheet wettability forming unit 27 may emit UV rays at an exposed upper surface of the sheet S held on the glass table 16. A surface Sa (see FIG. 2) of the sheet S is the exposed upper surface of the sheet S, where the liquid resin M fed from the resin feeding nozzle 183 may contact the sheet S (see FIG. 4). When the wettability of the surface Sa is higher, the liquid resin M may spread on the sheet S more easily.

Irradiating the surface Sa of the sheet S with UV rays may improve the wettability of the surface Sa of the sheet S due to a reason such that the UV rays may cause hydrophilic functional groups, such as OH groups, CO groups, CHO groups, and COOH groups, to grow on the surface Sa, and thereby the property of the sheet S may be modified. In particular, oxygen molecules in the air may be decomposed by the UV rays to generate ozone, and active oxygen may be generated from the ozone. The active oxygen generated from the ozone may react with molecules on the surface Sa of the sheet S and form new functional groups such as hydroxyl groups (OH), carbonyl groups (CO), aldehyde groups (CHO), and carboxyl groups (COOH). These functional groups exhibit high wettability, in other words, hydrophilicity. Therefore, wettability of the sheet S is improved by emitting UV rays thereat, and the liquid resin M is enabled to spread easily on the sheet S.

The insertion/withdrawal device 28 is configured to rotate about a rotation axis, which extends in the Z-axis direction. The insertion/withdrawal device 28 includes a supporting pole 281 containing the rotation axis and a supporting portion 282 extending from the supporting pole 281 in the horizontal direction. The sheet wettability forming unit 27 is fixed to a recess, which is formed in the supporting portion 282 and is open toward the glass table 16, and faces toward the glass table 16. As the insertion/withdrawal device 28 rotates about the rotation axis, the sheet wettability forming unit 27 along with the supporting portion 282 moves outward from the inside or inward from the outside of the space between the glass table 16 and the wafer holder 20. As such, the sheet wettability forming unit 27 is inserted in or withdrawn from the space between the glass table 16 and the wafer holder 20.

The protective member forming apparatus 1 is generally controlled by a controller 40. The controller 40 includes a processor to execute various processes and a storage (memory) to store various parameters and programs. The storage of the controller 40 stores, for example, a program to control the sheet wettability forming unit 27 in a series of processes in an operation to improve the wettability of the surface of the sheet S by emitting UV rays at the sheet S.

According to the protective member forming apparatus 1 configured as above, the wettability of the surface of the sheet S is improved by the sheet wettability forming unit 27, and the liquid resin M dropped on the sheet S may spread easily. Therefore, when the liquid resin M is pressed between the wafer W and the sheet S, the liquid resin M may spread over the wafer W entirely in a short time, and the protective member may be formed efficiently in a short time.

Furthermore, when the sheet S is in the highly wettable condition, in other words, when a contact angle of an adhesive agent is smaller, and the adhesive agent conforms well with a surface of an adherend, the adhesive agent may exhibit higher adhesion. As such, the improved wettability on the surface of the sheet S may improve adhesion of the liquid resin M to the sheet S. Thus, according to the protective member forming apparatus 1, a protective member adhered tightly to the wafer W may be formed.

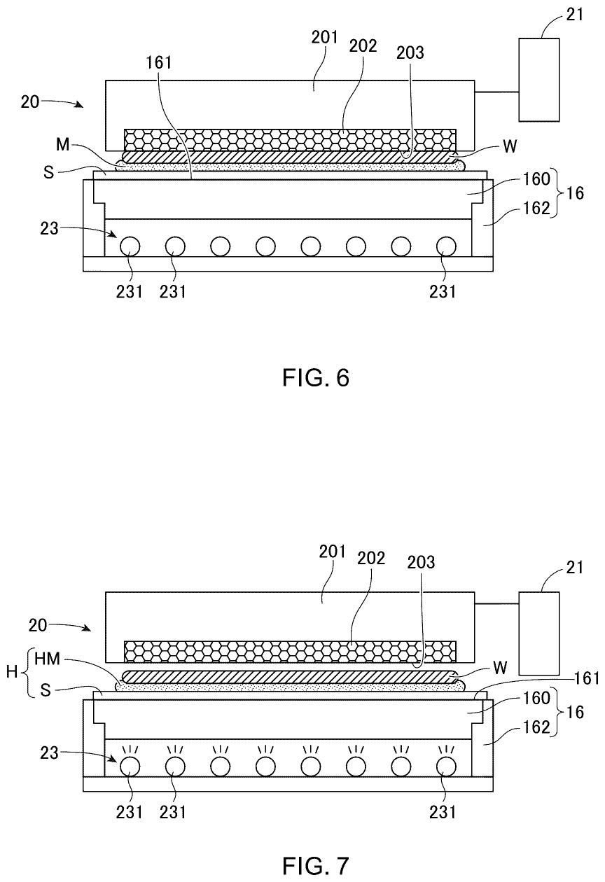

Next, a method for forming a protective member with the protective member forming apparatus 1 according to the embodiment will be described specifically. FIGS. 2 through 7 are illustrative views of processes for forming the protective member. FIG. 2 is an illustrative view of a sheet-feeding process. FIG. 3 is an illustrative view of a wettability-forming process. FIG. 4 is an illustrative view of a liquid-resin feeding process. FIG. 5 is an illustrative view of a wafer-holding process. FIG. 6 is an illustrative view of a press-spreading process. FIG. 7 is an illustrative view of a curing process.

FIG. 2 illustrates a sheet-loading process in forming the protective member. In the sheet-loading process, the controller 40 controls the sheet conveyer 17. The sheet conveyer 17 is controlled to cramp an end of the sheet S with the cramp 173 and move the arm 172 in the +Y direction (see FIG. 1). Accordingly, the sheet S is drawn out from the sheet feeder 171 and conveyed toward the glass table 16. The sheet S drawn out is cut to a predetermined length.

The controller 40 activates the suction source to cause the suction force to act on the suction holes 163, 164. Accordingly, the sheet S placed on the glass table 16 is suctioned and held against the glass table 16. At this point, an area of the sheet S is greater than an area of a lower surface Wb of the wafer W.

FIG. 3 illustrates the wettability-forming process. In the wettability-forming process, the sheet wettability forming unit 27 is located at a position above the sheet S placed on the glass table 16 in the sheet-loading process. In particular, the sheet wettability forming unit 27 is located at the position by the controller 40 operating the insertion/withdrawal device 28 to rotate and thereby inserting the supporting portion 282, to which the sheet wettability forming unit 27 is fixed, between the glass table 16 and the wafer holder 20.

After locating the sheet wettability forming unit 27 at the position, the controller 40 controls the sheet wettability forming unit 27 to emit UV rays at the surface of the sheet S held on the glass table 16. The surface of the sheet S at which the UV rays are emitted is the surface Sa opposite to the surface Sb held by the glass table 16. Accordingly, the wettability of the surface (surface Sa) of the sheet S is improved. When emission of the UV rays is completed, the controller 40 operates the insertion/withdrawal device 28 to rotate to withdraw the sheet wettability forming unit 27 from the position above the glass table 16. The wettability-forming process is thus completed.

FIG. 4 is an illustrative view of the liquid-resin feeding process in forming the protective member. In the liquid-resin feeding process, the resin feeding nozzle 183 of the resin feeder 18 is located above the sheet S having the surface, of which wettability has been improved in the sheet-wettability forming process. The resin feeding nozzle 183 is located above a central area of the glass table 16. For locating the resin feeding nozzle 183 at the position, the controller 40 controls the sheet conveyer 17 to move the arm 172 in the Y-axis direction.

After locating the resin feeding nozzle 183 at the position, the controller 40 controls the dispenser 181 to carry the liquid resin M from the tank 184 to the resin feeding nozzle 183 and cause the liquid resin M to drop from the resin feeding nozzle 183 onto the sheet S.

The liquid resin M dropped from the resin feeding nozzle 183 may fall on an area in proximity to a center of the surface Sa of the sheet S. Due to the wettability of the surface Sa of the sheet S improved in the preceding process, the liquid resin M dropping on the sheet S may spread from the central area peripherally.

The controller 40 may control the dispenser 181 based on information concerning, for example, a size of the wafer W to feed a specific amount (predetermined amount) of the liquid resin M that may sufficiently spread along the entire lower surface Wb of the wafer W. As the predetermined amount of the liquid resin M is completely fed to the sheet S, the controller 40 controls the arm 172 to move the resin feeding nozzle 183 to withdraw from the position above the glass table 16, and completes the liquid-resin feeding process.

FIG. 5 is an illustrative view of the wafer-holding process in forming the protective member. FIG. 5 shows the wafer holder 20 holding the wafer W in the wafer-holding process. In the wafer-holding process, the wafer W, prior to having the protective member H (see FIG. 7) formed thereon, is picked out from the cassette C by the first conveyer 12. Thereafter, the wafer W is passed to the second conveyer 25 and conveyed to the wafer holder 20. In the wafer holder 20, the suction source is activated, thereby causing the suction force to act on the porous member 202. The wafer holder 20 may thus use the suction force to suction the upper surface Wa of the wafer W and hold the wafer W against the wafer holding surface 203.

Optionally, the wafer-holding process may at least partly be performed in parallel (simultaneously) to the sheet-loading process, the wettability-forming process and the liquid-resin feeding process.

FIG. 6 is an illustrative view of the press-spreading process in forming the protective member. When the wafer W held by the wafer holder 20 is located above at a position to face the liquid resin M on the sheet S (see FIG. 5), the operation proceeds to the press-spreading process as shown in FIG. 6. In the press-spreading process, the controller 40 controls the motor 214 of the lift/lower device 21 to lower the lifting table 213 and the holding table 201 at a predetermined lowering speed.

As the holding table 201 lowers, the lower surface Wb of the wafer W approaches the glass table 16 and contacts the liquid resin M. Accordingly, the liquid resin M is pressed by the lower surface Wb of the wafer W and spreads in radial directions of the wafer W. The liquid resin M immediately before the contact with the lower surface Wb of the wafer W has spread to a certain extent due to the increased wettability of the surface Sa after dropping on the surface Sa of the sheet S. As the liquid resin M already having spread to some extent is pressed against the wafer W, the liquid resin M may spread further toward the outer edge of the wafer W, and thereby the entire surface of the wafer W may be covered with the liquid resin M in a short time.

Optionally, for adjusting the lowering amount of the holding table 201 according to the extent of spreading of the liquid resin M, the controller 40 may control the motor 214 based on a detected result from the load detector 22.

FIG. 7 is an illustrative view of the curing process in forming the protective member. In the curing process, the controller 40 controls the UV-emitting unit 23 to irradiate the liquid resin M with UV rays having an intensity and wavelength sufficient to harden the liquid resin M. In particular, the UV rays emitted at the placement surface 161 from the UV emitter 231 pass through the glass table 160 and the sheet S and reach the liquid resin M, which is the UV-curable resin, and cure the liquid resin M. When the liquid resin M is sufficiently cured, the UV-emitting unit 23 stops emitting the UV rays. With the cured liquid resin M, the protective member H composed of the resin HM, which is the cured liquid resin M, and the sheet S is formed to cover the lower surface Wb of the wafer W entirely, and the lower surface Wb of the wafer W is protected by the protective member H covering the lower surface Wb of the wafer W entirely.

According to the above embodiment, in the process to form the protective member H, before feeding the liquid resin M to the sheet S, wettability of the surface of the sheet S that will form the protective member H is improved. Therefore, even if, for example, a conventional sheet is used, rather than using a special sheet, the liquid resin M may spread in a short time entirely over the lower surface Wb of the wafer W. As a result, the protective member H may be formed efficiently in a short time. Optionally, wettability of the lower surface Wb of the wafer W may be improved before the liquid resin M is pressed and spread thereon.

Moreover, due to the improved wettability of the surface of the sheet S, adhesiveness of the liquid resin M, which serves as an adhesive agent, to the sheet S is improved. Therefore, the protective member H adhered tightly to the wafer W may be formed.

The protective member H is removed later. In this regard, a liquid resin having preferable removability may be selected as the liquid resin M. Therefore, even the adhesiveness of the liquid resin M to the sheet S may be improved by the improvement of the wettability, the improved adhesiveness may not cause excessive difficulty in removal of the protective member H. Optionally, for removing the protective member H from the wafer W, the protective member H may be ground with a grindstone. Furthermore, optionally, the protective member H may be irradiated with the UV rays once again so that the protective member H may be hardened further and may be ground with the grindstone thereafter.

FIG. 8 is an illustrative view of another example of the wettability-forming process in forming the protective member. FIG. 9 is an illustrative view of another liquid-resin feeding process in forming the protective member.

In the embodiment described above, an example of the process, in which the resin feeding nozzle 183 feeds the liquid resin M on the sheet S held by the glass table 16, was described. However, the resin feeding nozzle 183 may not necessarily feed the liquid resin M to the sheet S held by the glass table but may feed the liquid resin M to the wafer W held by the wafer holder.

Below, another method for forming the protective member H with a protective member forming apparatus by feeding the liquid resin M to the wafer W according to another embodiment will be described.

First, differences in a configuration of the protective member forming apparatus according to the present embodiment as shown in FIGS. 8 and 9 from the configuration of the protective member forming apparatus 1 will be described. The protective member forming apparatus according to the present embodiment differs from the protective member forming apparatus 1 in having a sheet holder 50 in place of the glass table 16 to hold the sheet S, having a wafer holder 70 in place of the wafer holder 20, the lift/lower device 21 being configured to uplift or lower the sheet holder 50 rather than the wafer holder 70, and having a wafer sheet wettability forming unit 32 additionally to a sheet wettability forming unit 31. The present embodiment describes an example, where a wafer sheet WS is adhered to the wafer W having bumps B formed on the surface thereof.

The sheet holder 50 differs from the glass table 16 in that the sheet holder 50 is arranged to have a holding surface 511 facing downward in the vertical direction, but the remainder of the sheet holder 50 is the same as the configuration of the glass table 16. The sheet holder 50 is a glass table, in a broad sense, having a glass table 51 and a supporting table 54, to hold the sheet S. The glass table 51 and the supporting table 54 correspond to the glass table 160 and the supporting table 162 in the glass table 16, respectively.

The sheet holder 50 is similar to the glass table 16 in that the sheet holder 50 accommodates a UV-emitting unit 53 including a plurality of UV emitters 531 inside. Moreover, the sheet holder 50 is similar to the glass table 16 in that the sheet holder 50 suctions to hold the sheet S. The sheet holder 50 may operate a suction force 60 to generate a suction force on the holding surface 511 of the sheet holder 50 through a suction path 52 and cause the sheet S to be suctioned and held against the holding surface 511. The UV-emitting unit 53 and the UV emitters 531 correspond to the UV-emitting unit 23 and the UV emitters 231, respectively.

The wafer holder 70 differs from the wafer holder 20 in that the wafer holder 70 is arranged to have a wafer holding surface 73 facing upward in the vertical direction, but the remainder of the wafer holder 70 is the same as the configuration of the wafer holder 20. The wafer holder 70 includes a holding table 71 and a porous member 72. The wafer holder 70 may operate a suction source 80 to generate a suction force on the wafer holding surface 73, which is a surface of the porous member 72, and cause the wafer W to be suctioned and held against the wafer holding surface 73. The holding table 71, the porous member 72, and the wafer holding surface 73 correspond to the holding table 201, the porous member 202, and the wafer holding surface 203 of the wafer holder 20, respectively.

In the protective member forming apparatus according to the present embodiment, the sheet holder 50 and the wafer holder 70 are in a vertically inverted arrangement from the glass table 16 and the wafer holder 20 in the protective member forming apparatus 1, respectively. Therefore, the liquid resin M ejected from the resin feeding nozzle 183 drops on the wafer W, more specifically, on a surface WSa being an upper surface of the wafer sheet WS adhered to the surface of the wafer W.

For the liquid resin M dropping from the resin feeding nozzle 183 to spread on the surface WSa, it is preferable that the surface WSa has higher wettability. The liquid resin M pressed between the surface WSa and the surface Sa being the lower surface of the sheet S held by the sheet holder 50 may spread in the radial directions of the wafer W. Therefore, in order for the liquid resin M to spread in a short time, it is preferable that both of the surfaces to come in contact with the liquid resin M have higher wettability, in other words, it is preferable that not only the surface WSa of the wafer W but also the surface Sa of the sheet S have higher wettability. In this regard, the protective member forming apparatus in the present embodiment has the sheet wettability forming unit 31 and the wafer sheet wettability forming unit 32.

The sheet wettability forming unit 31 may improve the wettability of the surface (surface Sa) of the sheet S by emitting UV rays at the surface (surface Sa) of the sheet S held on the sheet holder 50 (glass table). Meanwhile, the wafer sheet wettability forming unit 32 may improve the wettability of the surface WSa of the wafer sheet WS by emitting UV rays at the surface WSa of the wafer sheet WS adhered to the surface of the wafer W held on the wafer holder 70. The sheet wettability forming unit 31 and the wafer sheet wettability forming unit 32 are fixed to an insertion/withdrawal device 30 located in proximity to the sheet holder 50 and the wafer holder 70.

The insertion/withdrawal device 30 is configured to rotate about a rotation axis, which extends in the Z-axis direction. The insertion/withdrawal device 30 includes a supporting pole 300 containing the rotation axis and a supporting portion 301 and a supporting portion 302 extending from the supporting pole 300 in the horizontal direction. The supporting portion 301 and the supporting portion 302 are arranged to vertically overlap each other and supported by the supporting pole 300. The sheet wettability forming unit 31 is fixed to a recess formed in the supporting portion 301, which faces, among the supporting portion 301 and the supporting portion 302, toward the sheet holder 50, and is arranged to face toward the sheet holder 50. The wafer sheet wettability forming unit 32 is fixed to a recess formed in the supporting portion 302, which faces, among the supporting portion 301 and the supporting portion 302, toward the wafer holder 70, and is arranged to face toward the wafer holder 70.

As the insertion/withdrawal device 30 rotates about the rotation axis, the sheet wettability forming unit 31 and the wafer sheet wettability forming unit 32 along with the supporting portion 301 and the supporting portion 302 move outward from the inside or inward from the outside of a space between the sheet holder 50 and the wafer holder 70. As such, the sheet wettability forming unit 31 and the wafer sheet wettability forming unit 32 is inserted in or withdrawn from the space between the sheet holder 50 and the wafer holder 70.

According to the protective member forming apparatus configured as above, the protective member may be formed in processes similar to the processes performed in the protective member forming apparatus 1. In particular, first, the protective member forming apparatus performs a sheet-feeding process and a wafer-holding process. Thereby, the sheet S and the wafer W are held by the sheet holder 50 and the wafer holder 70, respectively. Thereafter, the protective member forming apparatus performs a wettability forming process as shown in FIG. 8.

FIG. 8 illustrates the wettability-forming process in forming the protective member. In the wettability-forming process, the sheet wettability forming unit 31 and the wafer sheet wettability forming unit 32 are located at the position between the wafer holder 70 and the sheet holder 50. In particular, the sheet wettability forming unit 31 and the wafer sheet wettability forming unit 32 are located at the position by the controller 40 operating the insertion/withdrawal device 30 to rotate to insert the supporting portion 301 with the sheet wettability forming unit 31 fixed thereto and the supporting portion 302 with the wafer sheet wettability forming unit 32 fixed thereto between the sheet holder 50 and the wafer holder 70.

After locating the sheet wettability forming unit 31 and the wafer sheet wettability forming unit 32 at the position, the controller 40 controls the sheet wettability forming unit 31 to emit UV rays at the surface Sa of the sheet S held on the sheet holder 50 and the wafer sheet wettability forming unit 32 to emit UV rays at the surface WSa of the wafer sheet WS of the wafer W held on the wafer holder 70. Thereby, wettability of the surfaces (surface Sa, surface WSa) of the sheet S and the wafer sheet WS is improved.

When emission of the UV rays is completed, the controller 40 operates the insertion/withdrawal device 30 to rotate to withdraw the sheet wettability forming unit 31 and the wafer sheet wettability forming unit 32 from the position between the wafer holder 70 and the sheet holder 50. The wettability-forming process is thus completed. After the wettability forming process, the liquid-resin feeding process is performed.

FIG. 9 is an illustrative view of the liquid-resin feeding process in forming the protective member. In the liquid-resin feeding process, the resin feeding nozzle 183 is located above the wafer sheet WS having the surface, of which wettability has been improved in the sheet-wettability forming process. The resin feeding nozzle 183 is located above a central area of the wafer holder 70.

After locating the resin feeding nozzle 183 at the position, the controller 40 controls the dispenser 181 to carry the liquid resin M from the tank 184 to the resin feeding nozzle 183 and cause the liquid resin M to drop from the resin feeding nozzle 183 onto the wafer sheet WS. The liquid resin M dropped from the resin feeding nozzle 183 may fall on an area in proximity to a center of the surface WSa of the wafer sheet WS. Due to the wettability of the surface WSa of the wafer sheet WS improved in the preceding process, the liquid resin M dropping on the sheet S may spread from the central area peripherally. After the liquid-resin feeding process, a press-spreading process is performed.

In the press-spreading process, the controller 40 controls the motor 214 of the lift/lower device 21 to lower the supporting table 54 at a predetermined lowering speed. As the supporting table 54 lowers, the surface Sa of the sheet S approaches the wafer holder 70 and contacts the liquid resin M. Accordingly, the liquid resin M is pressed against the surface Sa of the sheet S and spreads in radial directions of the wafer W. The liquid resin M immediately before the contact with the surface Sa of the sheet S has spread to a certain extent due to the improved wettability of the surface WSa of the wafer sheet WS after dropping on the surface WSa of the wafer sheet WS. As the liquid resin M already having spread to some extent is pressed by the wafer W, the liquid resin M may spread further toward the outer edge of the wafer W, and thereby the entire surface of the wafer W may be covered with the liquid resin M in a shorter time.

Finally, the curing process is performed. In the curing process, the controller 40 controls the UV-emitting unit 53 to irradiate the liquid resin M with UV rays having an intensity and wavelength sufficient to harden the liquid resin M. Thereby, the protective member consisting of the cured liquid resin M and the sheet S is formed on the wafer sheet WS. The curing process is substantially similar to the curing process performed by the protective member forming apparatus 1 as shown in FIG. 7 except that the UV rays are emitted from above.

According to the above embodiment, in the process to form the protective member, before feeding the liquid resin M to the sheet S, wettability of the surfaces of the adherends (sheet S, wafer W) that will contact the liquid resin M is improved. Therefore, the liquid resin M may spread between the sheet S and the wafer W, on the entire upper surface of the wafer sheet WS of the wafer W, in a short time. As a result, the protective member may be formed efficiently in a short time.

Optionally, after the surface of the wafer W, opposite to the surface on which the protective member is formed, is ground with a grindstone, the wafer W may be mounted on a ring frame by adhering the ground surface to the ring frame with dicing tape, and thereafter, the protective member may be removed along with the wafer sheet WS from the wafer W.

Embodiment of the present invention may not necessarily be limited to the configurations described above but may be modified, substituted, or altered in various ways without departing from the spirit of the technical idea of the present invention. Furthermore, if the technical idea of the present invention may be realized in a different way due to technological progress or other derived technology, it may be implemented with use of the method. Therefore, the claims cover all embodiments that may be included within the scope of the technical idea of the present invention.

In the embodiment described above, an example of the wettability forming unit configured to emit UV rays at the surface, of which wettability is to be improved, is described. However, the wettability forming unit may emit plasma in place of or in addition to UV rays. In the case where the wettability forming unit emits plasma, hydrophilic functional groups such as OH groups, CO groups, CHO groups, and COOH groups may as well be formed on the surface by the oxygen plasma. Therefore, wettability may be improved similarly to the case in which the wettability forming unit emits UV rays. In the other words, the wettability forming unit may be an emitter (a second emitter) configured to emit UV rays or plasma at a surface of the sheet held by the sheet holder and improve wettability of the surface of the sheet.

In the embodiment described above, an example of the sheet wettability forming unit configured to emit UV rays at the surface, of which wettability is to be improved, is described. However, the sheet wettability forming unit may emit plasma in place of or in addition to UV rays. In the case where the sheet wettability forming unit emits plasma, hydrophilic functional groups such as OH groups, CO groups, CHO groups, and COOH groups may as well be formed on the surface by the oxygen plasma. Therefore, wettability may be improved similarly to the case in which the sheet wettability forming unit emits UV rays. In the other words, the sheet wettability forming unit may be an emitter (a third emitter) configured to emit UV rays or plasma at a surface of a wafer sheet adhered to a surface of the wafer held by the wafer holder and improve wettability of the surface of the wafer sheet.

According to the embodiment described above, the glass table being an example of the sheet holder that holds the sheet placed thereon is explained. However, the sheet holder may not necessarily be limited to the glass table as long as it serves as a table to hold the sheet S. Meanwhile, in a case where the curing unit is configured to apply an external stimulus to the liquid resin through the sheet holder, it may be preferable that the sheet holder does not impede transmission of the external stimulus to the liquid resin. For example, in the case where UV rays serve as the external stimulus as described in the above embodiment, it is preferable that the sheet holder is a table made of a translucent material such as, for example, the glass table. It is desirable that the external stimulus be electromagnetic waves such as ultraviolet rays or infrared rays. In the other words, the curing unit may be an emitter (a first emitter) configured to emit electromagnetic waves to the liquid resin and cure the liquid resin.

The above embodiments described the example, in which the lift/lower device 21 is configured to lift or lower the wafer holder 20 relatively to the glass table 16 functioning as the sheet holder, and the example, in which the lift/lower device 21 lifts or lower the sheet holder 50 (glass table 51) relatively to the wafer holder 70. In other words, the lift/lower device 21 may lift or lower solely one of or both of the wafer holder and the sheet holder as long as the lift/lower device 21 lifts or lowers the wafer holder and the sheet holder relatively to each other.

### INDUSTRIAL APPLICABILITY

As described above, the protective member forming apparatus of the present invention may improve wettability of the surface of the sheet that the liquid resin contacts, thereby the liquid resin may be enabled to spread easily, and adhesiveness of the liquid resin after curing may be improved. Accordingly, a protective member adhesive tightly to a surface of a wafer may be formed in a short time, and the present invention is thus useful in a protective forming apparatus that may form a protective member on a surface of a wafer using a liquid resin.

What is claimed is:

1. A protective member forming apparatus configured to spread a liquid resin on an entire surface of a wafer on one side, cure the liquid resin and form a protective member to protect the entire surface of the wafer on the one side, comprising:
a sheet holder configured to hold a sheet;
a wafer holder configured to locate the wafer to face the sheet holder and hold the wafer thereat;
a liquid resin feeding nozzle configured to feed the liquid resin onto the sheet held by the sheet holder or onto the wafer held by the wafer holder;
a lift/lower device configured to lift or lower the sheet holder and the wafer holder relatively;
a first emitter configured to emit electromagnetic waves to the liquid resin and cure the liquid resin; and
a second emitter configured to emit UV rays or plasma at a surface of the sheet held by the sheet holder and improve wettability of the surface of the sheet.

2. The protective member forming apparatus according to claim 1, comprising a third emitter configured to emit UV rays or plasma at a surface of a wafer sheet adhered to a surface of the wafer held by the wafer holder and improve wettability of the surface of the wafer sheet.
